(19) United States
(12) Patent Application Publication
(10) Pub. No.: US 2026/0328825 A1
(43) Pub. Date: Oct. 22, 2026

(54) Light Extractor from Near-Surface Solid-State Color Centers

(71) Applicant: WISCONSIN ALUMNI RESEARCH FOUNDATION, Madison, WI (US)

(72) Inventors: Minjeong Kim, Madison, WI (US); Mikhail Kats, Madison, WI (US); Jennifer Choy, Madison, WI (US)

(21) Appl. No.: 19/186,168

(22) Filed: Apr. 22, 2025

(51) Int. Cl. G01R 29/12; G01K 11/12; G01L 1/24; G01R 33/032

(52) U.S. Cl. CPC G01R 29/12; G01K 11/12; G01L 1/24; G01R 33/032

(57) ABSTRACT

A crystalline silicon antenna positioned over a color center in an underlying host promotes the transmission of light from the host and/or into the host while providing a feature width of greater than 100 nm for simplified fabrication.

### STATEMENT REGARDING FEDERALLY SPONSORED RESEARCH OR DEVELOPMENT

N/A

### CROSS REFERENCE TO RELATED APPLICATION

### Background of the Invention

The present invention relates generally to color centers, being a type of crystal defect useful, for example, in sensor applications, and in particular to a structure facilitating the transmission of light into and out of the color center.

Color centers, for example negatively charged nitrogen vacancies (NVs) in diamond hosts or optically active spin defects in other semiconductor hosts, are optical emitters whose level-structure is highly sensitive to external perturbations, making them excellent sensors of highly localized electric and magnetic fields, temperature, and strain. Color centers are also of great interest for quantum computing and communication and the study of quantum phenomena such as quantum entanglement and superposition.

Efficiently measuring color center fluorescence is often challenging due to the high index of refraction of the wide-bandgap semiconductor hosts, which results in high reflectance of light passing through the host-air interfaces and total internal reflection for emission angles larger than the critical angle. Previous attempts to extract more light from color centers primarily involved the etching of the host itself which can degrade properties such as spin coherence and usually requires a dedicated etching system.

Improved light transmission from the host into the air may be promoted without etching or the like, by the addition of an antenna structure, for example, of crystalline silicon, applied on the host over the color center. The shape of the antenna may be determined, for example, by adjoint optimization, to maximize light emission into a particular direction or free-space mode for a particular orientation of the optically active spin defect. An example of this approach is described in Wambold, Raymond A. et al, “Adjoint-optimized nanoscale light extractor for nitrogen-vacancy centers in diamond” Nanophotonics, vol. 10, no. 1, 2021, pp. 393-401, hereby incorporated by reference. The resulting antenna shape is challenging to fabricate and sensitive to optically active spin defect orientation, making practical implementation difficult.

### SUMMARY OF THE INVENTION

The present inventors have developed a class of antenna designs that substantially increase transmission of light at the host/air interface while eliminating small feature-sizes that are difficult to fabricate and eliminating sensitivity to optically active spin defect orientation. The availability of this class of antennas greatly enhances the practicality of incorporating optically active spin defect centers into sensors and for other uses.

More specifically, the invention provides a color center device having a host formed of a wide bandgap semiconductor with optically active spin defects that act as color centers, the color centers operating to receive excitation light and to produce emitted light over a characteristic emission spectrum from the host surface. The invention provides an antenna of crystalline silicon positioned on the surface with an operative element dimensioned to promote a transmission of light from the host through the surface, and the antenna has a planar feature size along the surface greater than 100 nm.

It is thus a feature of at least one embodiment of the invention to develop a class of antenna shapes that can improve light transmission from and stimulation of color centers and that are more amenable to fabrication.

The outer planar periphery of the antenna may describe a convex set and/or be rotationally symmetric about a normal to the underlying surface of the host.

It is thus a feature of at least one embodiment of the invention to develop antennas that accommodate different optically active spin defect orientations with the antennas having large feature sizes while maximizing usable antenna area.

In some embodiments, the antenna may include a central opening providing a passage through the antenna to accept material to be analyzed into the antenna to a point proximate to the surface.

It is thus a feature of at least one embodiment of the invention to provide improved light transmission and close proximity between an analyte material and the NV centers.

These particular objects and advantages may apply to only some embodiments falling within the claims and thus do not define the scope of the invention.

### BRIEF DESCRIPTION OF THE DRAWINGS

FIG. 1 is a simplified perspective view of one embodiment of a color center device fabricated according to the teachings of the present invention and providing a diamond host with nitrogen vacancies and a crystalline silicon antenna;

FIG. 2 is a simplified plot of antenna diameter and antenna thickness versus a figure of merit with respect to light transmission between the host and the antenna showing multiple peaks represented by iso-figure of merit lines;

FIG. 3 is a process diagram for the manufacture of the antennas of FIG. 1 minimizing damage to the underlying host and showing, in a fragmentary inset, an elevational cross-section through the host and one antenna;

FIGS. 4a-4c are plan view cross-sections of alternative configurations for the antenna of FIG. 1; and

FIG. 5 is a geometric diagram of a hypothetical antenna profile showing a determination of feature width according to the present claims.

### DETAILED DESCRIPTION OF THE PREFERRED EMBODIMENT

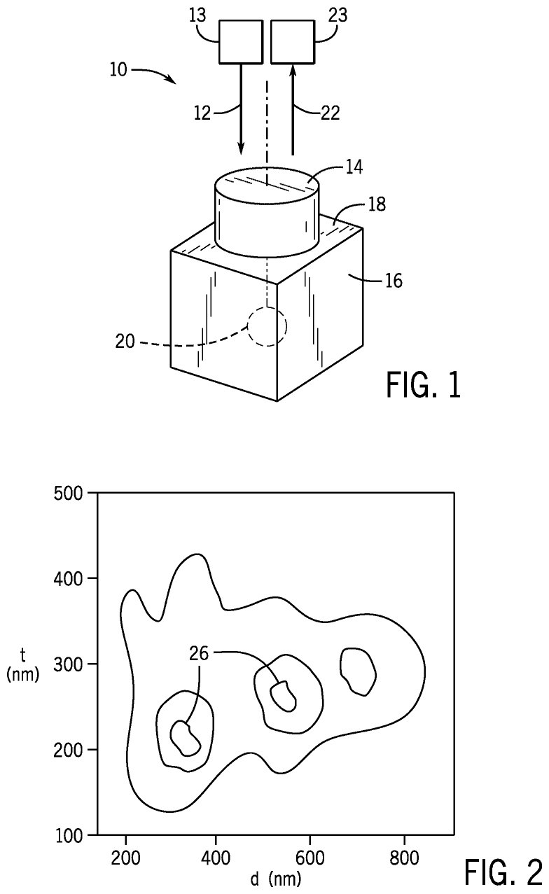

Referring now to FIG. 1, a color center device 10 may receive excitation light 12, for example, from a laser 13 providing a narrowband light signal. The excitation light 12 is oriented to pass wholly or in part through an antenna 14 and into host 16 through the host surface 18.

The host 16 holds nitrogen vacancies 20 in close proximity to the surface 18 (typically within 5 to 15 nm from the surface 18), the nitrogen vacancies 20 being optically active spin defects in the material of the host 16. These nitrogen vacancies 20 operate to create spin-active electronic transitions in host 16 that will receive the excitation light 12 (which can come from the top, bottom, and sides) to promote electrons to a higher energy level and to produce emitted light 22 when the promoted electrons decay to a lower energy level. The emitted light 22 will have characteristics (in terms of energy spectra and/or intensity) highly sensitive to the environment of the nitrogen vacancies 20 and will generally differ from the first frequency. This process of optical excitation and emission detection is often performed with addressing of microwave transitions using RF waves. Together these provide the basis of a sensor system for electrical and magnetic fields, temperature, and/or strain. The emitted light 22 may be received by a confocal microscope or the like and an electronic sensor for measurement of attenuation or frequency of light compared to a baseline in predetermined frequency ranges.

The host 16 may be selected from a variety of wide bandgap semiconductor materials including but not limited to diamond, silicon carbide, and hexagonal boron nitride. Desirable materials for the host 16 will generally provide the bandgap from 3 eV to 6.5 eV and/or a high index of refraction between 1.9 and 3.2. The host 16 also may be a so-called two-dimensional material, being a monolayer a few molecules thick, or may have the bulk properties of a three-dimensional material having a thickness in excess of 10 nm.

The antenna 14 operates to promote the coupling of light between the host 16 and the air by reducing internal reflection and Fresnel reflection and promoting Purcell enhancement. The Purcell effect increases emission rate so that more photons are emitted in the same time window, whereas the promotion of transmission improves the extraction of those photons. The current antenna 14 provides both of these benefits.

For this purpose, the antenna 14 and the host 16 will desirably have good light transmission properties in a desired frequency range encompassing the frequency of excitation light 12 and emitted light 22 and generally within a range of at least 300-1550 nm, allowing light to be received and transmitted from the nitrogen vacancies 20. Desirably, for this purpose, the antenna 14 is crystalline silicon for wavelengths greater than 500 nm. For wavelengths greater than 1000 nm, amorphous Si and polycrystalline Si may also be used. Alternatively, for wavelengths less than 500 nm, TiO₂ or ZnS or Ta₂O₅ or Nb₂O₅ or thin-film LiNbO₃. These latter materials may also be good in the other wavelength ranges.

Referring now to FIG. 2, the dimensions of the antenna 14 in diameter (d), measured generally parallel to the surface 18, and thickness (t) measured generally normal to the surface 18, may be evaluated by simulation against a spectrum average figure of merit which quantifies how much more light emerges from the host 16 normal to the host 16 in the presence of the antenna 14 than emerges from the bare host surface without the antenna 14. This figure of merit may account not only for collection enhancement but also the Purcell enhancement. In this example, the figure of merit considers light integrated to a resolution of 25 nm and reveals several maxima 26 for a given frequency of excitation light 12. One maximum 26 is identified to select a size of the antenna 14, in this case the diameter of a cylindrical antenna 14 and its thickness being the height of the cylinder. In one example, the height may be 220 nm and the diameter 500 nm to optimize a crystalline silicon antenna 14 for a wavelength of excitation light 12 of 635-800 nm with a diamond host. Other examples are provided below.

It will be recognized that the dimensions of the antenna 14 may be selected to individually or in combination maximize the transmission of both excitation light 12 and/or emitted light 22, and for this purpose, a dimension of the antenna 14 may be selected according to two plots based on both the frequency of excitation light 12 and the frequency of emitted light 22 and may represent a compromise between the maxima of the different plots rather than aligning with a single maximum of a single plot. Simulations suggest a potential of 17 times more photons will be collected with the antenna 14 in the case of NV centers in a diamond host 16, and experiments indicate an enhancement of approximately 9 times, the latter figure likely reduced because of lack of spatial alignment between the nitrogen vacancies 20 and antenna 14 in the test samples.

Example antenna dimensions for circular cylindrical antennas for various host materials are provided in the following Table I:

TABLE I

| Color center (and | Diameter | Thickness | Emission |
|---|---|---|---|
| host material) | (nm) | (nm) | Wavelength (nm) |
| NV - in diamond | 250 to 800 | 150 to 300 | 635-800 |
| NV - in diamond | 200 to 450 | 300 to 500 | |
| SiV in diamond | 500 to 750 | 150 to 250 | 735-745 |
| SiV in diamond | 850 to 1000 | 150 to 350 | |
| GeV in diamond | 350 to 450 | 100 to 200 | 598-608 |
| GeV in diamond | 500 to 650 | 200 to 250 | |
| GeV in diamond | 350 to 550 | 350 to 450 | |
| SnV in diamond | 150 to 250 | 250 to 350 | 614-624 |
| SnV in diamond | 350 to 550 | 100 to 350 | |
| SnV in diamond | 650 to 750 | 150 to 220 | |
| SiV in 4H—SiC | 150 to 750 | 200 to 450 | 850-1000 |
| SiV in 4H—SiC | 850 to 1000 | 150 to 500 | |
| VV 4H—SiC | 450 to 650 | 250 to 450 | 1000-1300 |
| VV 4H—SiC | 750 to 950 | 350 to 450 | |

Example antenna dimensions for square cross-sectional antennas for various host materials are provided in the following Table II:

TABLE II

| Color center (and | Side length | Thickness | Emission |
|---|---|---|---|
| host material) | (nm) | (nm) | Wavelength (nm) |
| NV - in diamond | 200 to 400 | 150 to 300 | 635-800 |
| SiV in diamond | 200 to 450 | 150 to 350 | 735-745 |
| GeV in diamond | 100 to 200 | 150 to 350 | 598-608 |
| GeV in diamond | 250 to 450 | 150 to 250 | |
| SnV in diamond | 350 to 450 | 150 to 250 | 614-624 |
| SnV in diamond | 500 to 700 | 200 to 300 | |
| SiV in 4H—SiC | 300 to 600 | 200 to 400 | 850-1000 |
| VV 4H—SiC | 400 to 600 | 250 to 400 | 1000-1300 |

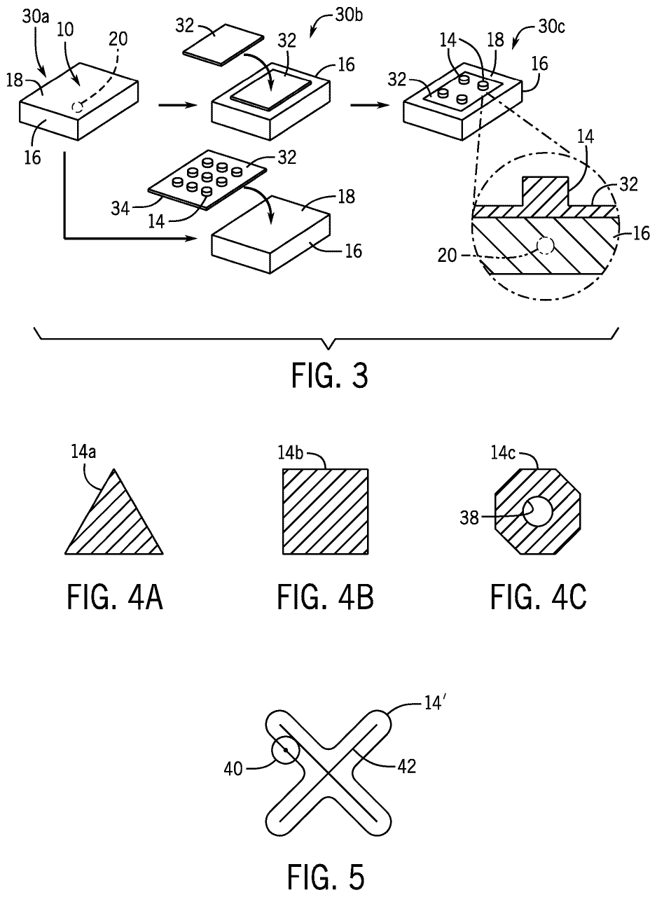

Referring now to FIG. 3, desirably fabrication of the color center device 10 will be performed by mechanical transfer of the antennas 14 to the host 16 to eliminate possible damage to the host surface 18 that might occur with in situ fabrication. Damage to the host surface 18 can decrease its effectiveness as an environmental sensor or other purposes.

In a first step 30a, the host 16 may be processed to create the embedded nitrogen vacancies 20, for example, using chemical vapor deposition (CVD) to create the single crystalline diamond host with less than 0.03 ppm nitrogen concentration. This diamond surface is then ion-implanted with nitrogen ions at an energy of 4-6 keV. Implantation is followed by a vacuum annealing at 800 degrees centigrade and tri-acid cleaning (equal parts nitric (HNO₃), perchloric (HClO₄), and sulfuric acids (H₂SO₄)).

Alternatively, the NV centers may be generated in diamond at a specific depth during chemical-vapor deposition (CVD) of diamond, which is sometimes referred to as “delta doping”

At step 30b, a silicon membrane 32, being a 220 nm layer of single-crystal silicon, is released from a silicon-on-insulator (SOI) wafer using a mixture of hydrogen fluoride (HF) and buffered oxide etchant (BOE). The membrane 32 may then be transferred onto the surface 18 of the diamond host 16 using an epitaxial lift-off technique describe, for example, at Konagai, M. et als., High Efficiency GaAs Thin Film Solar Cells by Peeled Film Technology, J Cryst Growth 1978, 45, 277-280 and Cheng, C. W.; Shiu, K. T.; Li, N.; Han, S. J.; Shi, L.; Sadana, D. K. Epitaxial Lift-off Process for Gallium Arsenide Substrate Reuse and Flexible Electronics. Nat Commun 2013, hereby incorporated by reference.

The individual antennas 14 may then be formed using electron-beam lithography. The inventors also contemplate that other fabrication techniques maybe use including DUV or nanoimprint which may reduce damage to the host. In this process, a 27 nm layer of SiO₂ may be deposited onto the upper surface of the silicon membrane 32 using PECVD as a hard mask. Arrays of circular patterns with a desired diameter (e.g., 500 nm) are then defined using electron-beam lithography. These patterns are transferred into the hard mask using ICP-RIE with CHF₃ and O₂. Finally, silicon antennas 14 are created by etching away of surrounding material using HBr and O₂ etching. The SiO₂ hard mask need not be removed as it is not expected to significantly affect the optical properties of the color center device 10 due to its low index and small thickness etching of a hard mask.

To protect the diamond surface 18 from O₂ plasma etching and to minimize unwanted contamination, particularly for near-surface nitrogen vacancies 20, a thin layer of the silicon membrane 32 may be left on top of the host 16 around the antennas 14 during and after the etching process, this thin layer of silicon membrane 32 having a thickness of 20-30 nm.

Referring still to FIG. 3, in an alternative embodiment, step 30c may be implemented on the silicon membrane 32 as supported by a carrier 34 to pre-form the antennas 14 by etching. In this case the thin layer 32 is not retained. The antennas 14 may then be transferred to the upper surface 18 of the host by a stamping process where the antennas 14 are pressed against the exposed silicon and held by van der Waals forces.

The invention contemplates a variety of different shapes of antenna 14 may be employed which are all readily fabricated using lithographic techniques. In the circular cylindrical configuration of FIG. 1, the circular profile of the pillar ensures an ability to accommodate all possible orientations of the nitrogen vacancies 20 in (100)-oriented diamond eliminating the need for rotational alignment between the antenna 14 and the host 16. Other rotationally symmetric cross-sections for the antennas 14 are also contemplated, for example, as shown in FIGS. 4a-4c. Such shapes include planar cross-sectional profiles that are regular polygons including but not limited to a triangle, square, octagon and the like.

Rotational symmetry, as used herein, also known as radial symmetry in geometry, is the property a shape has when it looks the same after rotation by a partial turn. An object's degree of rotational symmetry is the number of distinct orientations in which it looks exactly the same for each rotation.

Desirably the antennas 14 may also be constrained to shapes with convex outer surfaces and more specifically to shapes whose planar outer peripheries define a convex set. An outer periphery is a convex set if every segment joining two points on the outer periphery contains only points within the periphery. In this definition, the area within the outer periphery excludes holes fully surrounded by the outer periphery.

Any of the antennas 14 may also include a central opening 38 (shown in FIG. 4c), for example, having a 50 nm or greater diameter to provide central access to and capture of a received analyte solution or other material, allowing that material to locate close to the surface 18 and hence the nitrogen vacancies 20. This opening can substantially promote sensitivity of the nitrogen vacancies 20 to the analyte solution and its environmental modifications.

The antennas 14 desirably provide coarse planar feature widths that can be readily fabricated by lithographic or similar techniques and transferred to a host 16 without danger of etch-through and with low sensitivity to tolerance variations and which are relatively robust against tilted sidewalls (e.g., conical frustum shapes rather than exact cylinders). The present invention contemplates a class of antennas having a feature width measured along the plane of the host of greater than 100 nm.

Referring to FIG. 5, “feature width” or “feature-size” as defined herein is the diameter of a smallest diametered circle 40 parallel to a plane of the host 16 having a center on a peripheral edge of the antenna 14 and a tangent point on a medial axis 42 of the antenna 14 outline. A medial axis 42 of an object is a set of all points having more than one closest point on the object's periphery.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

The term planar as used herein refers to measurements along a plane of the substrate and thickness refers to measurements normal to the substrate and generally aligned with the direction of light propagation to the light sensor and from the light source.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

It is specifically intended that the present invention not be limited to the embodiments and illustrations contained herein and the claims should be understood to include modified forms of those embodiments including portions of the embodiments and combinations of elements of different embodiments as come within the scope of the following claims. All of the publications described herein, including patents and non-patent publications, are hereby incorporated herein by reference in their entireties.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

What we claim is:

1. A color center device comprising:
a host formed of a wide bandgap semiconductor with optically active spin defects providing a color center, the color center operating to receive excitation light at a first range of frequencies to produce emitted light at a different second range of frequencies from the host surface; and
an antenna of crystalline silicon positioned on the surface and providing an operative element dimensioned to promote a transmission of light from the host through the surface, wherein the antenna has a planar feature size along the surface greater than 100 nm.

2. The color center device of claim 1 wherein an outer planar periphery of the antenna describes a convex set.

3. The color center device of claim 1 wherein an outer planar periphery of the antenna is rotationally symmetric about a normal to the host.

4. The color center device of claim 1 wherein the antenna includes a central opening providing a passage through the antenna to accept material to be analyzed into the antenna to a point proximate to the surface.

5. The color center device of claim 1 wherein the optically active spin defects are within 20 nm from the host surface.

6. The color center device of claim 1 wherein host has a bandgap from 3 eV to 6.5 eV.

7. The color center device of claim 1 wherein index of refraction from 1.9 to 3.2.

8. The color center device of claim 1 wherein the host is selected from the group consisting of diamond, silicon carbide, and hexagonal boron nitride.

9. The color center device of claim 1 wherein the optically active spin defects are nitrogen vacancies.

10. The color center device of claim 9 wherein the host is diamond and the diameter of the antenna is between 250 and 800 nm and the thickness of the antenna is between 150 and 300 nm.

11. The color center device of claim 1 wherein the optically active spin defects are silicon vacancies and the host is silicon carbide and the diameter of the antenna is between 150 and 1000 nm and the thickness is between 150 and 500 nm.

12. The color center device of claim 1 wherein the host is hexagonal boron nitride.

13. The color center device of claim 1 wherein further including a laser illuminating the color center and a light sensor electronically sensing light emitted by the color center.

14. A method of sensing environmental conditions using a color center device having:
a host formed of a wide bandgap semiconductor with optically active spin defects providing a color center, the color center operating to receive excitation light at a first range of frequencies through a host surface to produce emitted light at a second different range of frequencies from the host surface; and
an antenna of crystalline silicon positioned on the surface and providing an operative element dimensioned to promote a transmission of light from the host through the surface, wherein the antenna has a planar feature size along the surface greater than 100 nm; the method comprising:
(a) stimulating the color center to excite electrons into a higher energy level; and
(b) measuring emitted light during decay of the electrons from the higher energy level to a lower energy level to provide a measure of at least one of electrical field, magnetic field, temperature, and material strain.

15. The method of claim 14 wherein the antenna is adapted to promotes Purcell emissions from the color center.
